(19) United States
(12) Patent Application Publication
(10) Pub. No.: US 2007/0228417 A1
(43) Pub. Date: Oct. 4, 2007

(54) Semiconductor device and method of fabricating the same

(75) Inventor: Nobuaki Yasutake, Kanagawa (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/723,965

(22) Filed: Mar. 22, 2007

(30) Foreign Application Priority Data
Apr. 3, 2006 (JP) 2006-102547

(51) Int. Cl. H01L 31/00

(52) U.S. Cl. 257/192

(57) ABSTRACT

A semiconductor device according to an embodiment of the present invention includes: a semiconductor substrate; a gate electrode formed on the semiconductor substrate through a gate insulating film; a source/drain region formed apart from the gate electrode; and a source/drain extension region formed between the gate electrode and the source/drain region so as to be shallower than the source/drain region; in which a buried film made of a crystal having a lattice constant different from that of an Si crystal is buried in at least a part of the source/drain region and the source/drain extension region.

### CROSS-REFERENCE TO RELATED APPLICATIONS

This application is based upon and claims the benefit of priority from prior Japanese Patent Application No. 2006-102547, filed on Apr. 3, 2006, the entire contents of which are incorporated herein by reference.

### BACKGROUND OF THE INVENTION

The present invention relates to a semiconductor device fabricated by utilizing a selective epitaxial growth technique, and a method of fabricating the same.

A semiconductor device to which a strained silicon technique using a selective epitaxial growth technique is introduced in fabricating process is known as conventional one. This sort of semiconductor device, for example, is disclosed in Japanese Patent KOKAI No. 2006-13428.

In fabrication of this sort of semiconductor device, for example, a silicon substrate of a p-metal oxide semiconductor (p-MOS) transistor is selectively etched away to form therein a recess portion, and a crystal having a lattice constant different from that of silicon of a substrate is selectively, epitaxially grown in the resulting recess portion while it is doped with impurity ions to form a source/drain region, whereby a compressive strain is generated in a crystal lattice of silicon of a channel region between the source region and the drain region by applying a stress to the channel region between the source region and the drain region. Here, a source/drain extension region is formed by implanting ions of a p-type impurity into a surface of the silicon substrate by utilizing an ion implantation method.

According to this semiconductor device, the compressive strain is generated in the crystal lattice of silicon of the channel region, which results in that a mobility of electric charges in silicon of the p-MOS transistor can be increased, and thus the excellent transistor characteristics can be obtained.

However, although the source/drain region is formed of the epitaxial layer, no epitaxial layer exists in the source/drain extension region. Thus, an interval of the epitaxial layers of the source region and the drain region becomes wide. As a result, there is encountered such a problem that the compressive strain is reduced which is generated in the crystal lattice of the silicon of the channel region between the source region and the drain region. The reduction in compressive strain makes it impossible to desire a sufficient increase in mobility of the electric charges.

### BRIEF SUMMARY OF THE INVENTION

A semiconductor device according to one embodiment of the present invention includes:

a semiconductor substrate;

a gate electrode formed on the semiconductor substrate through a gate insulating film;

a source/drain region formed apart from the gate electrode; and

a source/drain extension region formed between the gate electrode and the source/drain region so as to be shallower than the source/drain region;

in which a buried film made of a crystal having a lattice constant different from that of an Si crystal is buried in at least a part of the source/drain region and the source/drain extension region.

A method of fabricating a semiconductor device according to another embodiment of the present invention includes:

forming a gate electrode on a semiconductor substrate through a gate insulating film;

etching the semiconductor substrate by using the gate electrode as a mask, thereby forming a first recess portion in the semiconductor substrate;

forming a spacer so as to cover a side face of the gate electrode and a side face, on a side of the gate electrode, of an inner surface of the first recess portion;

etching the semiconductor substrate by using both the gate electrode and the spacer as a mask, thereby forming a second recess portion in the semiconductor substrate; and

epitaxially growing a crystal having a lattice constant different from that of an Si crystal in the first and second recess portions.

### BRIEF DESCRIPTION OF THE DRAWINGS

FIG. 1A is a cross sectional view of a semiconductor device according to a first embodiment of the present invention;

FIG. 1B is a partially enlarged view of the vicinity of a gate of the semiconductor device according to the first embodiment of the present invention;

FIGS. 2A to 2J are respectively cross sectional views showing processes for fabricating the semiconductor device according to the first embodiment of the present invention;

FIG. 3A is a cross sectional view of a semiconductor device according to a second embodiment of the present invention;

FIG. 3B is a partially enlarged view of the vicinity of a gate of the semiconductor device according to the second embodiment of the present invention;

FIGS. 4A to 4D are respectively cross sectional views showing processes for fabricating the semiconductor device according to the second embodiment of the present invention; and

FIG. 5 is a graph showing results of a simulation about a relationship between a threshold voltage shift and a gate length in the semiconductor device according to the second embodiment of the present invention.

### DETAILED DESCRIPTION OF THE INVENTION

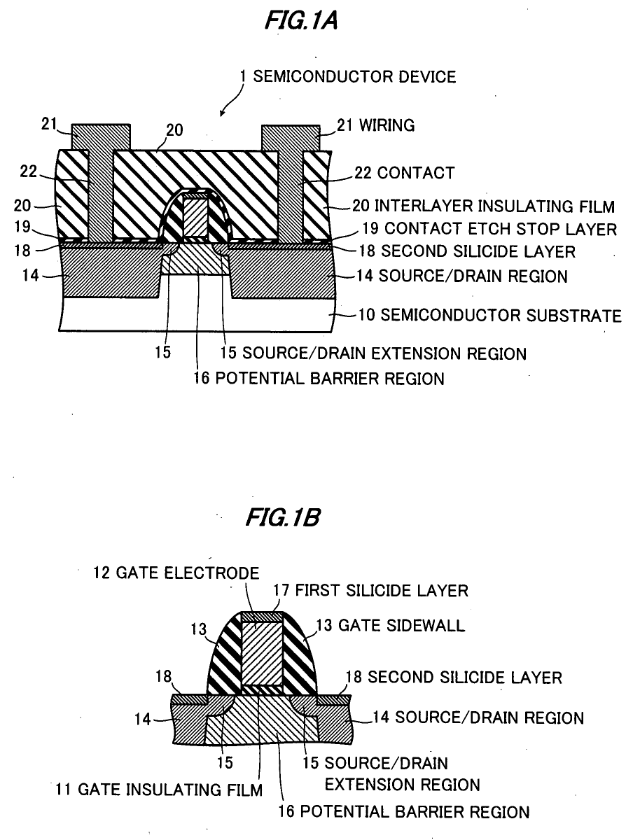

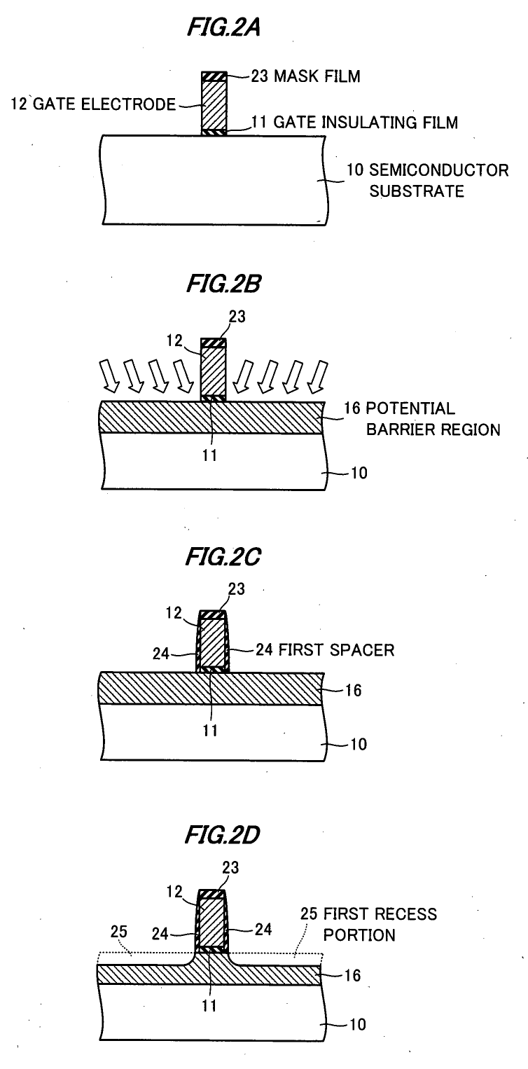

FIG. 1A is a cross sectional view of a semiconductor device according to a first embodiment of the present invention, and FIG. 1B is a partially enlarged view of the vicinity of a gate of the semiconductor device according to the first embodiment of the present invention.

A semiconductor device 1 generally includes a gate electrode 12 which is formed on a semiconductor substrate 10 through a gate insulating film 11, a gate sidewall 13 which is formed on a side face of the gate electrode 12, a source/drain region 14 and a source/drain extension region 15 which are formed in the vicinity of a surface of the semiconductor substrate 10, a potential barrier region 16 which is formed between the source/drain regions 14 and also between the corresponding source/drain extension regions 15, and is formed right under the gate insulating film 11, a first silicide layer 17 which is formed in the vicinity of a surface of the gate electrode 12, a second silicide layer 18 which is formed in the vicinity of a surface of the source/drain region 14, an interlayer insulating film 20 which is formed on the structure portion including the above-mentioned constituent elements through a contact etch stop layer 19, and a contact 22 which is formed in the interlayer insulating film 20 and through which a wiring 21 and the second silicide layer 18 contact each other.

An Si substrate, for example, can be used as the semiconductor substrate 10.

The gate insulating film 11, for example, is made of SiON, SiO₂ or the like.

The gate electrode 12, for example, is made of polycrystalline Si, polycrystalline SiGe or the like, and the first silicide layer 17 made of a compound of a metal such as Ni, Pt, Co, Er, Pd or NiPt, and silicon is formed on an exposed portion of the gate electrode 12.

The gate sidewall 13 may have a structure of a single layer which, for example, is made of SiN, SiO₂ or the like, a structure of two layers which, for example, are made of SiN and SiO₂, or a structure of three or more layers.

The source/drain region 14 and the source/drain extension region 15 are formed by epitaxially growing a crystal in a recess portion which is formed in the vicinity of the surface of the semiconductor substrate 10 by utilizing a suitable etching method. However, the source/drain region 14 and the source/drain extension region 15 need not to strictly agree with the region made of the epitaxially grown crystal. For example, when an impurity contained in the epitaxially grown crystal diffuses into the semiconductor substrate 10, the source/drain region 14 and the source/drain extension region 15 become generally, slightly larger than the region made of the epitaxially grown crystal.

A crystal having a lattice constant different from that of the Si crystal of which the semiconductor substrate 10 is made can be used as the crystal which is to be epitaxially grown in order to form the source/drain region 14 and the source/drain extension region 15. More specifically, in the case of the p-channel transistor, a crystal such as an SiGe crystal which is doped with a p-type impurity such as B, BF₂ or In, and which has a lattice constant larger than that of the Si crystal can be used as the crystal which is to be epitaxially grown in order to form the source/drain region 14 and the source/drain extension region 15. On the other hand, in the case of an n-channel transistor, a crystal such as an SiC crystal which is doped with an n-type impurity such as P or As, and which has a lattice constant smaller than that of the Si crystal can be used as the crystal which is to be epitaxially grown in in order to form the source/drain region 14 and the source/drain extension region 15.

The use of the crystal, such as the SiGe crystal or the SiC crystal, having the lattice constant different from that of the Si crystal causes a strain to generate in a portion which lies between the source/drain regions 14 and also between the source/drain extension regions 15 and in which a channel region is formed. As a result, it is possible to obtain an effect of strained silicon (an improvement in a mobility of electric charges). For example, when the crystal, such as the SiGe crystal, having the lattice constant larger than that of the Si crystal is used, a compressive strain is applied to the portion in which the channel region is formed. On the other hand, when the crystal, such as the SiC crystal, having the lattice constant smaller than that of the Si crystal is used, a tensile strain is applied to the portion in which the channel region is formed.

In the case of the p-channel transistor, preferably, a Ge concentration of the SiGe crystal of which each of the source/drain region 14 and the source/drain extension region 15 is made is in the range of 10 to 30 atomic %. On the other hand, in the case of the n-channel transistor, preferably, a C concentration of the SiC crystal of which each of the source/drain region 14 and the source/drain extension region 15 is made is not higher than 3 atomic %. When the Ge concentration of the SiGe crystal is lower than 10 atomic %, the insufficient strain is applied to the portion in which the channel region is formed. Also, when the Ge concentration of the SiGe crystal exceeds 30 atomic %, crystal defects occurs in the semiconductor substrate 10 or the like. These crystal defects may cause a leakage current. On the other hand, when the C concentration of the SiC crystal exceeds 3 atomic %, likewise, the crystal defects occurs in the semiconductor substrate 10 or the like. These crystal defects may cause a leakage current.

A depth of the source/drain region 14 (a depth when a position of a bottom portion of the gate insulating film 11 is set as a reference) is preferably in the range of 50 to 100 nm. When the depth of the source/drain region 14 is smaller than 50 nm, the insufficient strain is applied to the portion in which the channel region is formed. On the other hand, when the depth of the source/drain region 14 exceeds 100 nm, a short channel effect may increase.

A depth of the source/drain extension region 15 (a depth when the position of the bottom portion of the gate insulating film 11 is set as the reference) is preferably in the range of 3 to 20 nm. When the depth of the source/drain extension region 15 is smaller than 3 nm, the insufficient strain is applied to the portion in which the channel region is formed. On the other hand, when the depth of the source/drain extension region 15 exceeds 20 nm, the short channel effect may increase.

A distance from a boundary between the source/drain region 14 and the source/drain extension region 15 to an end portion of the gate insulating film 11 closer to the boundary along a direction parallel to the surface of the semiconductor substrate 10 is preferably in the range of 5 to 30 nm. When this distance is smaller than 5 nm, the short channel effect may increase. On the other hand, when this distance exceeds 30 nm, it is difficult to realize the high integration because the size of the transistor becomes too large.

In the case of the p-channel transistor, the potential barrier region 16, for example, is formed by implanting an n-type impurity such as As or P into the surface of the semiconductor substrate 10. On the other hand, in the case of the n-channel transistor, the potential barrier region 16, for example, is formed by implanting a p-type impurity such B, BF₂ or In into the surface of the semiconductor substrate 10.

That is to say, by forming the potential barrier region 16 by implanting the impurity of a conductivity type different from that of each of the source/drain 14 and the source/drain extension region 15 into the surface of the semiconductor substrate 10, the threshold voltage can increase, thereby suppressing the short channel effect.

The second silicide layer 18, for example, is made of a compound of a metal such as Ni, Pt, Co, Er, Pd or NiPt, and silicon and is formed on the surface of the source/drain region 14.

The contact 22 which, for example, is made of W is formed in the interlayer insulating film 20 which, for example, is made of SiO₂, and the wiring 21 which, for example, is made of Al or Cu, and the second silicide layer 18 contact each other through the contact 22.

The contact etch stop layer 19 which, for example, is made of SiN is formed for the purpose of suppressing an etching damage which the second silicide layer 18 and its periphery receive when a contact hole is formed in the interlayer insulating film 20 by utilizing a suitable etching method in order to form the contact 22 in the interlayer insulating film 20.

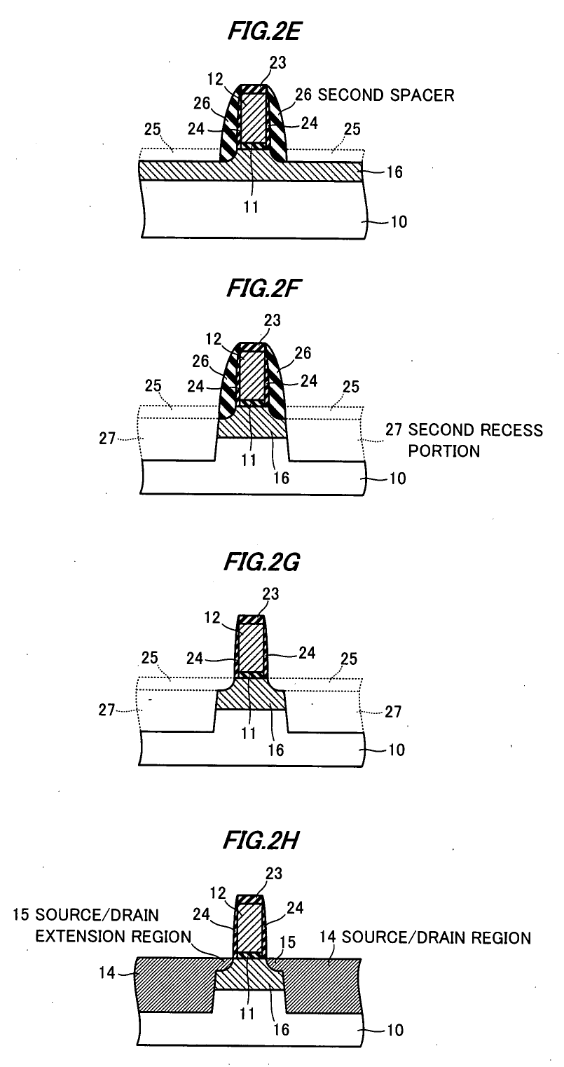

FIGS. 2A to 2J are respectively cross sectional views showing processes for fabricating the semiconductor device according to the first embodiment of the present invention.

Firstly, as shown in FIG. 2A, the gate insulating film 11, the gate electrode 12, and a mask layer 23 are formed in order on the semiconductor substrate 10 in a photo resist process, a reactive ion etching (RIE) process, and the like. It should be noted that although the mask film 23 acts as a mask for the gate electrode 12, it is not essential to the processes for fabricating the semiconductor device 1 according to the first embodiment of the present invention.

Next, as shown in FIG. 2B, for example, ions of an n-type impurity are implanted from a part above the surface of the semiconductor substrate 10 in the case of the p-channel transistor while ions of a p-type impurity are implanted therefrom in the case of the n-channel transistor, thereby forming the potential barrier region 16. At this time, the ions of the impurity are implanted into the surface of the semiconductor substrate 10 at a predetermined angle (for example, 20°) with respect to a direction vertical to the surface of the semiconductor substrate 10, which results in that the potential barrier region 16 can be formed in a region as well right under the gate insulating film 11. Here, performing a heat treatment or anneal processing after completion of the implantation of the impurity ions prompts the impurity ions to diffuse into the semiconductor substrate 10. As a result, it is possible to extend the potential barrier region 16.

Note that, formation of the potential barrier region 16 may be performed before formation of the gate insulating film 11, the gate electrode 12, and the mask layer 23.

Next, as shown in FIG. 2C, a first spacer 24 which, for example, is made of SiN is formed on a side face of the gate electrode 12 in an RIE process or the like. It should be noted that although the first spacer 24 acts as an offset spacer or the like, it is not essential to the processes for fabricating the semiconductor device 1 according to the first embodiment of the present invention.

Next, as shown in FIG. 2D, the surface of the semiconductor substrate 10 containing the surface of the potential barrier region 16 is selectively etched away in the RIE process or the like, thereby forming a first recess portion 25. Here, the semiconductor substrate 10 is made of single crystal silicon and have the surface which is exposed so as to face the first recess portion 25 and acts as a base for epitaxial growth of the single crystal silicon.

Next, as shown in FIG. 2E, a second spacer 26 which, for example, is made of SiO₂ is formed on a side face of the first spacer 24. A bottom portion of the second spacer 26 contacts the surface of the semiconductor substrate 10 containing the surface of the potential barrier region 16 within the first recess portion 25. Here, the second spacer 26 is preferably made of a material different from (a material different in an etching resistance from) each of the materials of the mask layer 23 and the first spacer 24.

Next, as shown in FIG. 2F, the surface of the semiconductor substrate 10 containing the surface of the potential barrier region 16 is selectively etched away in the RIE process or the like by using the second spacer 26 as a mask, thereby forming a second recess portion 27. Here, the semiconductor substrate 10 is made of single crystal silicon and have the surface which is exposed so as to face the second recess portion 27 and acts as a base for the epitaxial growth of the single crystal silicon.

Next, as shown in FIG. 2G, the second spacer 26 is removed by utilizing an etching method in the RIE process or the like. In this connection, when the second spacer 26 is made of a material (for example, SiO₂ and SiN) different from each of the materials of the mask layer 23 and the first spacer 24, only the second spacer 26 can be selectively removed because the second spacer 26 is different in the etching resistance from each of the materials of the mask layer 23 and the first spacer 24.

Next, as shown in FIG. 2H, for example, a B-doped SiGe crystal is epitaxially grown on the surface of the semiconductor substrate 10 exposed so as to face each of the first and second recess portions 25 and 27 in the case of the p-channel transistor, and an As-doped SiC crystal is epitaxially grown thereon in the case of the n-channel transistor, thereby forming the source/drain region 14 and the source/drain extension region 15. At this time, no epitaxial growth occurs on the upper surface of the gate electrode 12 due to the presence of the mask film 23.

The crystal of which each of the source/drain region 14 and the source/drain extension region 15 is made is grown to reach approximately the same position as that of the bottom portion of the gate insulating film 11. The epitaxial growth of that crystal is performed within a chemical vapor deposition chamber. In this case, for example, monosilane (SiH₄) or dichlorosilane (SiH₂Cl₂) is used as a raw material for Si, germanium hydride (GeH₄) is used as a raw material for Ge, diborane (B₂H₆) is used as a raw material for B, acetylene (C₂H₂) is used as a raw material for C, and arsine (AsH₃) is used as a raw material for As. Under this condition, the epitaxial growth is performed at a temperature of 700 to 850° C. in an ambient atmosphere of a hydrogen gas or the like.

Next, as shown in FIG. 2I, after the mask film 23 and the first spacer 24 are removed by utilizing an etching method in the RIE process or the like, the gate sidewall 13 is formed on a side face of the gate electrode 12 in the RIE process or the like.

Next, as shown in FIG. 2J, when a heat treatment is performed after sputtering is performed from a part above the semiconductor substrate 10 to form a metal film made of Ni, Pt, Co, Er, Pd or NiPt, a silicidization reaction occurs in the vicinities of a contact surface between the metal film and the gate electrode 12, and a contact surface between the metal film and the source/drain region 14. As a result, the first silicide layer 17 and the second silicide layer 18 are formed in the vicinities of the surfaces of the gate electrode 13 and the source/drain region 14, respectively.

After that, after the unreacted metal film is removed, the contact etch stop layer 19 and the interlayer insulating film 20 are formed in this order on the substrate. Also, the wiring 21, the contact 22 through which the wiring 21 and the silicide layer 18 contact each other, and the like are formed in order, thereby obtaining the semiconductor device 1 shown in FIG. 1A.

According to the first embodiment of the present invention, each of the source/drain region 14 and the source/drain extension region 15 is formed of the epitaxial crystal layer, which results in that it is possible to apply the sufficient strain to the crystal lattice of silicon of the channel region between the source region and the drain region, and thus it is possible to suppress the short channel effect. More specifically, the epitaxial crystal layer is formed in two-step structure having the source/drain region 14 and the source/drain extension region 15, which results in that an interval of the epitaxial crystal layers between which the channel region is formed is made small in the vicinity of the surface of the substrate, thereby applying the sufficient strain to the crystal lattice of silicon of the channel region. Also, the interval of the epitaxial crystal layers between which the channel region is formed is made large in an inside of the substrate. Thus, the short channel effect is suppressed.

In addition, after the potential barrier region 16 is formed, the first and second recess portions 25 and 27 are formed by utilizing the suitable etching method, and the source/drain region 14 and the source/drain extension region 15 are then formed therein. Hence, although the impurity ions are implanted into the surface of the semiconductor substrate 10 when the potential barrier region 16 is formed, the source/drain region 14 and the source/drain extension region 15 (at least the region of the epitaxial crystal layer) are free of those impurity ions of the conductivity type different from that of each of the source/drain region 14 and the source/drain extension region 15. As a result, it is possible to reduce the junction capacity, and thus it is possible to realize the high operating speed of the transistor.

Moreover, the epitaxial crystal layer having the two-step structure is collectively formed. Thus, no impurity in the source/drain extension region 15 diffuses into the channel region in the phase of the epitaxial growth for formation of the source/drain region 14, unlike in the case where the formation of the recess portion and the epitaxial growth in the recess portion for the source/drain extension region 15, and the formation of the recess portion and the epitaxial growth in the recess portion for the source/drain region 14 are performed in the individual processes, respectively. As a result, it is possible to avoid the situation that the short channel effect may increase due to an increase in diffusion length of the impurity in the source/drain extension region 15.

In addition, since it is possible to avoid the situation that the short channel effect may increase by preventing the impurity from diffusing from the source/drain extension region 15 into the channel region in the manner as described above, the impurity concentration in the source/drain extension region 15 can be increased up to a level of being substantially equal to that in the source/drain region 14. As a result, it is possible to reduce the electrical resistance of the source/drain extension region 15.

In addition, since the surface of the semiconductor substrate is scraped in the phase of the gate processing in terms of the manufacturing process, it is difficult to shallow the junction depth of the source/drain extension region 15 by the related art. However, according to the first embodiment of the present invention, the very shallow junction can be readily formed because the junction depth of the source/drain extension region 15 can be adjusted in accordance with the etching depth.

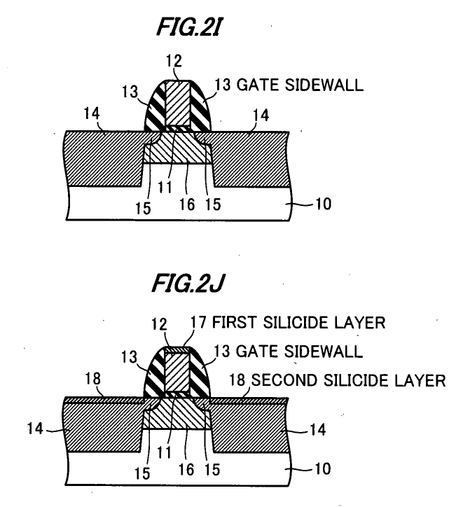

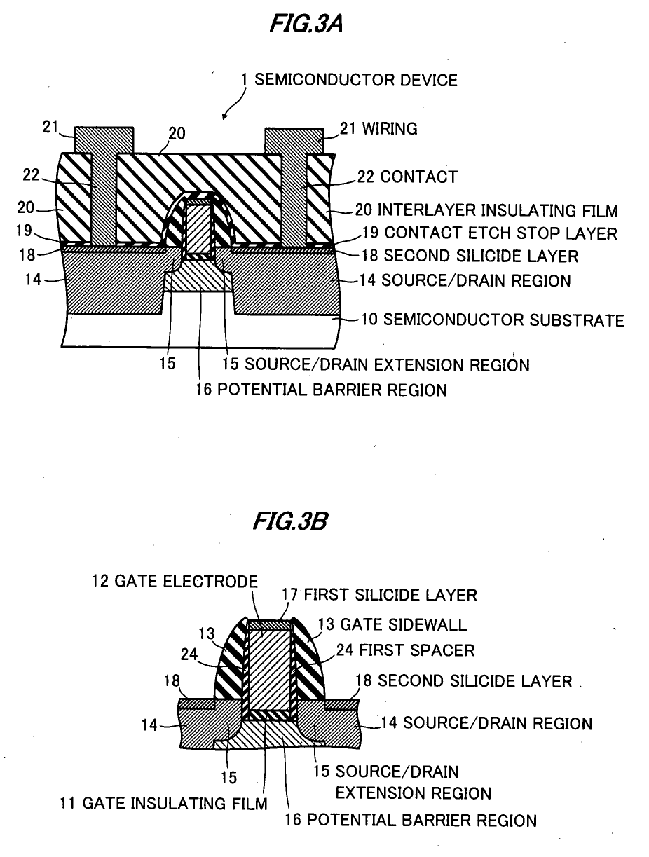

FIG. 3A is a cross sectional view of a semiconductor device according to a second embodiment of the present invention, and FIG. 3B is a partially enlarged view of the vicinity of a gate of the semiconductor device according to the second embodiment of the present invention. The semiconductor device 1 according to the second embodiment of the present invention has a raised source/drain structure in which each of the surfaces of the source/drain region 14 and the source/drain extension region 15 is located in a position higher than that of the bottom portion of the gate insulating film 11. Thus, the semiconductor device 1 according to the second embodiment of the present invention is different from the semiconductor device 1 according to the first embodiment of the present invention in depths of the source/drain region 14 and the source/drain extension region 15 from the surface of the substrate, and the structure of a gate sidewall film. Here, a description of the same respects such as other structures, and materials of the respective portions as those in the first embodiment is omitted here for the sake of simplicity.

The depths of the source/drain region 14 and the source/drain extension region 15 when the position of the bottom portion of the gate insulating film 11 is set as the reference are the same as those in the semiconductor device 1 according to the first embodiment. However, since the semiconductor device 1 according to the second embodiment has the raised source/drain structure, the depths of the source/drain region 14 and the source/drain extension region 15 from the surface of the substrate are deeper than those of the semiconductor device 1 according to the first embodiment.

The gate sidewall film includes the gate sidewall 13 and the first spacer 24. The first spacer 24 is formed between the gate insulating film 11 and the source/drain extension region 15.

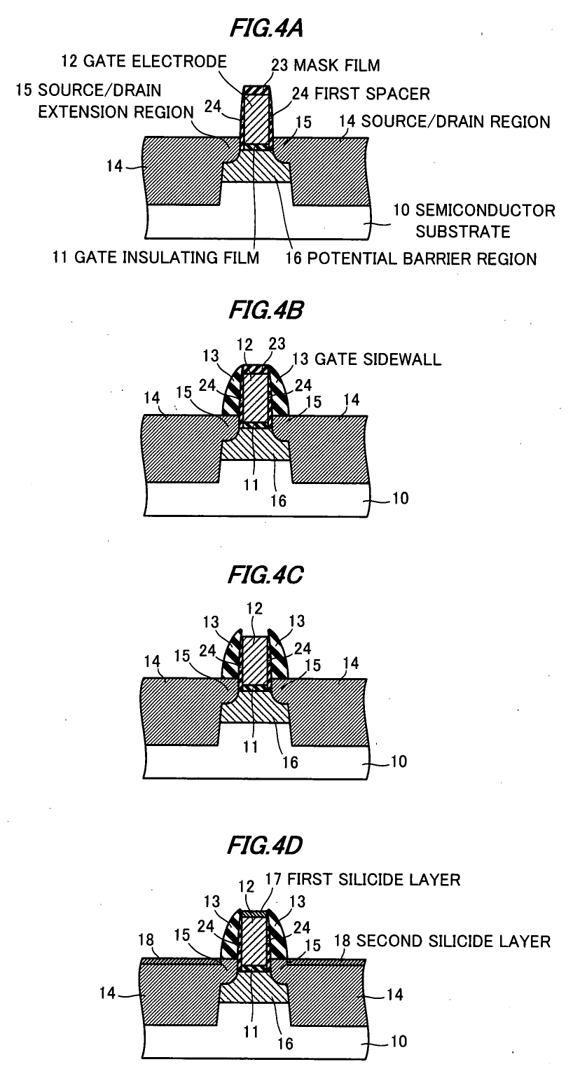

FIGS. 4A to 4D are respectively cross sectional views showing processes for fabricating the semiconductor device according to the second embodiment of the present invention. Note that, since the processes until the first and second recess portions 25 and 27 are formed by utilizing the suitable etching method shown in FIGS. 2A to 2G are the same as those in the first embodiment, a description thereof is omitted here for the sake of simplicity.

Firstly, after completion of the processes until the process shown in FIG. 2G, as shown in FIG. 4A, for example, a B-doped SiGe crystal is epitaxially grown on the surface of the semiconductor substrate 10 exposed so as to face each of the first and second recess portions 25 and 27 in the case of the p-channel transistor, and an As-doped SiC crystal is epitaxially grown thereon in the case of the n-channel transistor, thereby forming the source/drain region 14 and the source/drain extension region 15. At this time, the crystal is epitaxially grown until each of the surfaces of the source/drain region 14 and the source/drain extension region 15 reaches the position higher than that of the bottom portion of the gate insulating film 11.

Here, preferably, a height from the bottom portion of the gate insulating film 11 to each of the surfaces of the source/drain region 14 and the source/drain extension region 15 is not larger than 30 nm. When the height exceeds 30 nm, the operating speed of the semiconductor device 1 may be reduced because the overlap between the source/drain region 14 and the gate electrode 12 becomes large, so that a parasitic capacity occurs.

Next, as shown in FIG. 4B, the gate sidewall 13 is formed on the side face of the first spacer 24. At this time, the gate sidewall 13 is also formed on a part of the surface of the source/drain extension region 15.

Next, as shown in FIG. 4C, the mask film 23 formed on the upper surface of the gate electrode 12 is removed by utilizing the etching method in the RIE process or the like. In this connection, when the gate sidewall 13 is made of a material(s) (for example, SiO₂ and SiN) different from that of each of the mask film 23 and the first spacer 24, only the mask film 23 and an upper portion of the first spacer 24 adjacent to the mask film 24 can be selectively removed from a difference in the etching resistance between the gate sidewall 13, and each of the mask layer 23 and the first spacer 24.

Next, as shown in FIG. 4D, when a heat treatment is performed after sputtering is performed from a part above the semiconductor substrate 10 to form a metal film made of Ni, Pt, Co, Er, Pd or NiPt, a silicidization reaction occurs in the vicinities of a contact surface between the metal film and the gate electrode 12, and a contact surface between the metal film and the source/drain region 14. As a result, the first silicide layer 17 and the second silicide layer 18 are formed in the vicinities of the surfaces of the gate electrode 12 and the source/drain region 14, respectively.

After that, after the unreacted metal film is removed, the contact etch stop layer 19 and the interlayer film 20 are formed in this order on the substrate. Also, the wiring 21, the contact 22 through which the wiring 21 and the second silicide layer 18 contact each other, and the like are formed in order, thereby obtaining the semiconductor device 1 shown in FIG. 3A.

According to the second embodiment of the present invention, the raised source/drain structure is adopted as the structure of the semiconductor device 1, which results in that the depths of the source/drain region 14 and the source/drain extension region 15 from the surface of the regions 14 and 15 can be increased while the depths of the source/drain region 14 and the source/drain extension region 15 from the reference position, which is the position of the bottom portion of the gate insulating film 11, are suppressed equally to those in the first embodiment, thereby reducing the electrical resistance corresponding thereto.

Note that, although in this embodiment, the first spacer 24 is left and is used as a part of the gate sidewall film, a structure may be adopted in which the first spacer 24 is removed, and only the gate sidewall 13 constitutes the gate sidewall film.

In addition, an elevated source/drain structure may also be adopted in which of the source/drain region 14 and the source/drain extension region 15, only the source/drain region 14 is formed to reach a position higher than that of the bottom portion of the gate insulating film 11.

The results of calculating a simulation about the short channel effect occurring in the semiconductor device 1 according to the second embodiment of the present invention will be shown hereinafter. In this simulation, the p-channel transistor was used as the semiconductor device 1, and was compared with a semiconductor device of a comparative example.

Here, the semiconductor device of the comparative example had a structure in which of the source/drain region and the source/drain extension region, only the source/drain region was formed of the epitaxial layer. Also, in order to obtain the same strained silicon effect as that in the semiconductor device 1 of this embodiment, a distance between the source region and the drain region between which the channel region was formed was reduced.

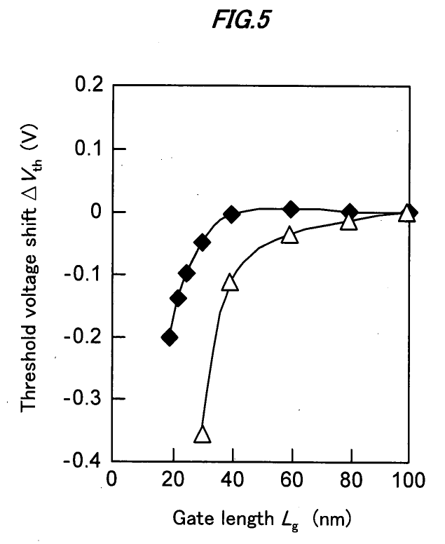

FIG. 5 is a graph showing a relationship between ΔVₜₕ (threshold voltage shift) (V) and L_{g} (gate length) (nm). The threshold voltage shifts represent the threshold voltages in the respective gate lengths in the case where the threshold voltage when the gate length is 100 nm is set as a reference (differences between the threshold voltage when the gate length is 100 nm and the respective threshold voltages). In FIG. 5, a mark ♦ represents the value obtained about the semiconductor device 1 of this embodiment, and a mark Δ represents the value obtained about the semiconductor device of the comparative example.

The magnitude of the threshold voltage shift is correlative to that of the short channel effect. Thus, it is possible to judge that when the threshold voltage shift falls within the range of 0 to −0.2 V as an approximate index, the short channel effect is suppressed to a level allowing the semiconductor device to be put to practical use.

From the graph of FIG. 5, it is understood that even when the gate length is reduced to 20 nm in the case of the semiconductor device 1 of this embodiment, the short channel effect is suppressed to the level allowing the semiconductor device 1 to be put to practical use. On the other hand, it is also understood therefrom that in the case of the semiconductor device of the comparative example, it is difficult to reduce the gate length to 30 nm or less because the short channel effect abruptly increases as the gate length decrease from the vicinity of 40 nm. It is thought that in the case of the semiconductor device of the comparative example, the short channel effect due to the impurity ions diffused from the epitaxial layer into the channel region increases because the distance between the source region and the drain region is small between which the channel region is formed.

Note that, in the comparative example described above, it is possible to suppose the structure in which the introduction of the impurity ions to the epitaxial layer is performed not in the phase of the selective epitaxial growth, but after the selective epitaxial growth by utilizing the ion implantation method, and only a portion of the epitaxial layer located apart from the channel region to some extent is doped with the impurity ions by taking measures of, for example, using a mask. In this case, the short channel effect can be suppressed because the diffusion of the impurity ions from the epitaxial layer into the channel region is suppressed. However, the strain applied to the portion in which the channel region is formed may become small because the crystal of which the epitaxial layer is made may be damaged by the ion implantation, so that the lattice defects or lattice strains may occur.

As the results of comparing the simulation calculated for a compressive stress applied to the channel region in the semiconductor device 1 (p-channel transistor) of this embodiment with that in the semiconductor device of the comparative example described above, it was found that the compressive stress falling in the practicable range of −900 to −1,000 MPa is obtained in both the semiconductor devices.

From the simulation results described above, it was understood that although if it is tried to apply the sufficient compressive strain to the channel region in the case of the semiconductor device of the comparative example, the short channel effect increases, in the case of the semiconductor device 1 of this embodiment, the sufficient compressive strain can be applied to the channel region while the short channel effect is suppressed.

In addition, as the results of performing a simulation about an impurity profile simulation in the semiconductor device 1 (p-channel transistor) of this embodiment, it was understood that although the impurity ions of a conductivity type different from that of each of the source/drain region and the source/drain extension region are implanted into the surface of the semiconductor substrate when the potential barrier region is formed, each of the source/drain region and the source/drain extension region is free of these impurity ions.

It should be noted that the present invention is not intended to be limited to the above-mentioned first and second embodiments, and various changes thereof can be implemented without departing from the gist of the invention. For example, although the above-mentioned first and second embodiments have been described by using the bulk substrate as the semiconductor substrate, the present invention is not limited thereto. For example, a silicon on insulator (SOI) substrate or the like can be used as the semiconductor substrate.

In addition, the constituent elements of the above-mentioned first and second embodiments can be arbitrarily combined with one another without departing from the gist of the invention.

What is claimed is:

1. A semiconductor device, comprising:
a semiconductor substrate;
a gate electrode formed on the semiconductor substrate through a gate insulating film;
a source/drain region formed apart from the gate electrode; and
a source/drain extension region formed between the gate electrode and the source/drain region so as to be shallower than the source/drain region;
wherein a buried film made of a crystal having a lattice constant different from that of an Si crystal is buried in at least a part of the source/drain region and the source/drain extension region.

2. A semiconductor device according to claim 1, wherein the crystal having the lattice constant different from that of the Si crystal has the lattice constant larger than that of the Si crystal.

3. A semiconductor device according to claim 2, wherein the crystal having the lattice constant larger than that of the Si crystal is an SiGe crystal.

4. A semiconductor device according to claim 3, wherein a Ge concentration of the SiGe crystal is in a range of 10 to 30 atomic %.

5. A semiconductor device according to claim 2, wherein the semiconductor device functions as a p-channel transistor.

6. A semiconductor device according to claim 1, wherein the crystal having the lattice constant different from that of the Si crystal has the lattice constant smaller than that of the Si crystal.

7. A semiconductor device according to claim 6, wherein the crystal having the lattice constant smaller than that of the Si crystal is an SiC crystal.

8. A semiconductor device according to claim 7, wherein a C concentration of the SiC crystal is not higher than 3 atomic %.

9. A semiconductor device according to claim 6, wherein the semiconductor device functions as an n-channel transistor.

10. A semiconductor device according to claim 1, wherein a depth, of the buried film buried in the source/drain extension region, from the gate insulating film is not smaller than 3 nm, and not larger than 20 nm.

11. A semiconductor device according to claim 1, wherein a depth, of the buried film buried in the source/drain region, from the gate insulating film is not smaller than 50 nm, and not larger than 100 nm.

12. A semiconductor device according to claim 1, wherein the buried film is free of an impurity of a conductivity type different from that of each of the source/drain region and the source/drain extension region.

13. A semiconductor device according to claim 1, wherein each of surfaces of the source/drain region and the source/drain extension region exists in a position higher than that of a bottom portion of the gate insulating film.

14. A semiconductor device according to claim 1, wherein the buried film is formed collectively in the source/drain region and the source/drain extension region.

15. A method of fabricating a semiconductor device, comprising:
forming a gate electrode on a semiconductor substrate through a gate insulating film;
etching the semiconductor substrate by using the gate electrode as a mask, thereby forming a first recess portion in the semiconductor substrate;
forming a spacer so as to cover a side face of the gate electrode and a side face, on a side of the gate electrode, of an inner surface of the first recess portion;
etching the semiconductor substrate by using both the gate electrode and the spacer as a mask, thereby forming a second recess portion in the semiconductor substrate; and
epitaxially growing a crystal having a lattice constant different from that of an Si crystal in the first and second recess portions.

16. A method of fabricating a semiconductor device according to claim 15, wherein the crystal having the lattice constant different from that of the Si crystal has the lattice constant larger than that of the Si crystal.

17. A method of fabricating a semiconductor device according to claim 16, wherein the crystal having the lattice constant larger than that of the Si crystal is an SiGe crystal.

18. A method of fabricating a semiconductor device according to claim 15, wherein the crystal having the lattice constant different from that of the Si crystal has the lattice constant smaller than that of the Si crystal.

19. A method of fabricating a semiconductor device according to claim 18, wherein the crystal having the lattice constant smaller than that of the Si crystal is an SiC crystal.

20. A method of fabricating a semiconductor device according to claim 15, wherein the crystal having the lattice constant different from that of the Si crystal is epitaxially grown to a position higher than that of a bottom portion of the gate insulating film.
